(19) United States
(12) Patent Application Publication
(10) Pub. No.: US 2005/0190559 A1
(43) Pub. Date: Sep. 1, 2005

(54) Light-emitting diode arrangement comprising a reflector

(76) Inventor: Hans Kragl, Diekholzen (DE)

Correspondence Address: Daniel H. Bliss;Bliss McGlynn, P.C., 2075 West Big Beaver Road, Suite 600, Troy, MI, 48084, US

(21) Appl. No.: 11/116,833

(22) Filed: Apr. 28, 2005

(30) Foreign Application Priority Data
Oct. 29, 2002 (DE) 102 50 383.4

(51) Int. Cl. H01L 29/22

(52) U.S. Cl. 362/296

(57) ABSTRACT

A light-emitting diode arrangement comprises a sub-mount on which a light-emitting diode chip is mounted, and a reflector which is adjusted at the sub-mount and has a reflector surface located in the beam path of the light-emitting diode chip. The reflector is formed from the lateral wall of a solid body consisting of a transparent material and having a small irradiation surface located opposite the light-emitting diode chip (3) and a large radiation surface which is located opposite the same, at a distance, a lateral wall forming a reflector surface extending therebetween, and the sub-mount comprises an opening into which the reflector body is inserted, with the irradiation surface first.

### FIELD OF THE INVENTION

The present invention refers to a light-emitting diode arrangement with reflector, comprising a sub-mount on which a light-emitting diode chip is mounted, and a reflector aligned at the sub-mount and comprising a reflector surface located in the beam path of the light-emitting diode chip.

### BACKGROUND OF THE INVENTION

The illumination with light of light-emitting diodes (LEDs) has a number of advantages compared to the illumination with light from conventional light sources, particularly light bulbs: The life of LEDs with up to 100,000 hours is plural times longer than the life of light bulbs, the color may be changed in almost any manner by selecting a suitable LED, the color temperature of a lamp composed of a plurality of differently colored LEDs may be set electronically and the electro-optical efficiency of LED radiators is higher nowadays compared to the efficiency of classical light bulbs.

An immense multitude of different illumination applications and tasks exist. From the diffuse background illumination of a wall or signal panel, over traffic signal lamps, lamps for the color control in the printing or textile industry, spot-like radiating light sources for object illumination up to the illumination by means of optical waveguides, different radiation sources are required in the various fields of application.

An LED chip typically radiates light from the chip surface in an isotropic manner, i.e. it radiates regularly in each direction. At a certain distance to the chip a so-called Lambert-shaped beam distribution is obtained: The light intensity is the highest perpendicular to the chip surface, and it decreases in each direction proportional to the cosine of the angle with respect to the perpendicular. (Physical explanation in this respect e.g. in Gerthsen, Kneser, Vogel: Physik, 13^{th} edition, page 417 et seq.). The consequence of this is that the LED chip radiates at an angle of 45° perpendicularly to its surface in total the highest optical power, since the product of cosine (Lambert radiation) and sine (spherical surface element) has its maximum at 45°. These physically given radiation properties must be taken into consideration when designing lamps and lamp bodies.

### PRIOR ART

From WO 02/054129 A1 which is the starting point of the invention according to the preamble of claim 1, an illumination means is known consisting of a disc of a light-conductive material to whose edge a plurality of LEDs are coupled in juxtaposition via individual coupling elements, wherein the coupling elements comprise a recess having a paraboloidal, metallized wall and wherein an LED-carrying sub-mount is arranged on the bottom of the recess. In this document, a coupling arrangement is also described, in which the LED-carrying sub-mount is formed as a micro-reflector and a coupling element for connecting an optical waveguide is aligned thereon, said micro-refelctor comprising a paraboloidal deflection mirror to enable a connection of the optical waveguide in a flat manner.

An opto-electonic component on which an optical waveguide is attached which has a cross section expanding or constricting from the component and which serves for bridging the distance between a circuit board carrying he component and a housing front plate is known from the essay of F. Möllmer and G. Waitl: “Siemens SMT-TOPLED für die Oberflächenmontage, TEIL 2: Hinweise zur Anwendung”, in Siemens Components 29 (1991), volume 5, pg. 193-196. The structure of the component is explained in more detail in DE 197 55 734 A1. According thereto it consists of a lead frame whose individual conductors that are isolated from one another are connected to one another by a cast material, which at the same time forms a reflector surface, and of an opto-electronic semi-conductor element that is directly mounted on the lead frame and is bonded thereto.

According to DE 197 55 734 A1, a lens can be set onto the body formed by the cast material, said lens being centered at the body and opposing the semiconductor element at a distance, wherein the gap is filled by a transparent cast material. The reference does not mention anything about the procedure how the semiconductor element is being positioned on the lead frame. For this purpose the die bond technology is known by the aid of which positioning accuracies which are better than ±70 μm, however, cannot be achieved. The space available in the component shown for the storage of the semiconductor element, indeed allows such tolerances.

Illumination devices via optical waveguides have become more popular during the last years. The light of the radiator must for this purpose be coupled into the optical waveguide, which, however, only conveys light up to a predetermined maximum angle against the optical waveguide axis. Light that is incident at greater angles is not guided by the optical waveguide but is radiated. As to the light source supplying the optical waveguide, this means that this source ideally is to couple light into the optical waveguide only in such a manner that said light is further conveyed by the optical waveguide. That means that the light source shall not exceed a certain maximum radiation angle that depends on the type of the optical waveguide.

The light coupling into an optical waveguide with a high efficiency is also meaningful for the optical data transfer.

It has been known for a long time that reflectors improve the radiation characteristics of LEDs. Typically, LEDs used for illumination purposes are set onto a lead frame carrier that is designed in a funnel-shaped manner, it is wire bonded and cast with a transparent over-mold. FIG. 1 shows this structure. As may be seen from this Figure, a reflector is arranged around the LED chip, however it reflects light emitted laterally from the LED only to a small extent into the direction of the axis. Particularly the light radiated at a 45° angle irradiates the inner wall of the plastic body and is radiated towards the front after a total reflection at an angle of 60°. For a light source that shall output directed light, this light is mostly lost. The limit angle of the total reflection is 42° for PMMA, i.e. light that is radiated at less than 48° with respect to the vertical of the chip and that irradiates the vertical wall of the plastic body is totally reflected. The reason for the flat design of the reflector according to FIG. 1 is basically seen in the technological restrictions defined by the lead frame technology and by the easy die bonding in the flat reflector.

In order to still be able to utilize the light from LEDs in plastic housings of a diameter of 5 mm, which is radiated at steep angles to the vertical, reflectors are known from the prior art that can be set onto the plastic housing. Reference is made as an example to a catalog of the company Osram München, page 97 and to a catalog of the distributor company Conrad, Hirschau, 2002, page 1097, according to which the reflector set on top increases the light intensity in the direction of the observer up to a factor 5. However, it can be recognized from the geometry of the reflector shown in the catalog that the light cannot be directed to an extent greater than ±45°. Since the reflector having a diameter of 12 mm is relatively large, its longitudinal extension and therefore the narrower bundling of the light would lead to component sizes that are difficult to handle. Moreover, the exposed, sensitive inner surface of the mirror of the reflector set on top is to a restricted extent only suitable for hard ambient conditions.

An elegant solution was introduced by the company Gaggione SA, France, on the fair Optatec 2002. According thereto, the 5 mm LED is inserted into a hole in the focal point of a parabolic reflector manufactured from a not metallized, solid, transparent plastic material. Light that exits the 5 mm LED body at an angle that is too large is reflected forwards by total reflection in the plastic body. The arrangement is well protected against outer influences (dust, water etc.), however, the reflector is very large compared to its directional effect. Moreover, considerable light gets lost by reflection at the interface between the 5 mm LED and the reflector.

### SUMMARY OF THE INVENTION

The object of the invention is to provide a light-emitting diode arrangement that can be used as a lamp, in which the light of the LED is bundled with a high efficiency to form a relatively narrow beam cone.

This object is solved by the features defined in claim 1. Further embodiments of the invention are subject matter of the dependent claims.

The invention allows the application e.g. as signal lamp of a rail vehicle, which ideally only illuminates in the direction of the rails. However, a spot radiator as well that radiates in an aimed manner onto an object to be illuminated (exhibit in a museum, cigarette lighter in a motor vehicle, food illumination in a supermarket etc) requires directed light.

The invention discloses an arrangement of a micro-structured sub-mount, consisting of an accommodation opening for the precise, accurately matched accommodation of the LED chip in the focal point of a paraboloid which is formed in the sub-mount as a metallic reflector mirror around the LED chip. An extension reflector is set onto or into the sub-mount, said extension reflector taking over the beam formation outside of the reflector in the sub-mount. The LED chip is electrically contacted by at least one bond wire, which extends through a slot in the sub-mount and is connected to a carrier carrying the electrical supply lines.

The invention and its advantages as well as further features of the invention will now be described in detail with reference to the drawings.

### SHORT DESCRIPTION OF THE DRAWINGS

FIG. 1 schematically shows in an enlarged scale a 5 mm plastic housing with an LED chip accommodated therein according to the prior art.

FIG. 2 shows in cross section the schematic diagram of a first embodiment of the invention:

FIG. 3 shows in cross section that solution corresponding to FIG. 2 supplemented by a housing for supporting the reflector body:

FIG. 4 shows an illumination body with several LED chips attached on the edge of a light-conducting disc having a paraboloidal cross section and serving as a reflector body;

FIG. 5 shows an arrangement comparable to FIG. 4, however with a circular disc having a paraboloidal axial section and serving as a reflector body, and

FIG. 6 shows an arrangement in which the reflector body is delimited by four lateral surfaces, which together in sectional planes perpendicular to the LED chip form right angles, but have a paraboloidal curvature in a plane parallel to the vertical on the LED chip.

### DETAILED DESCRIPTION OF THE INVENTION

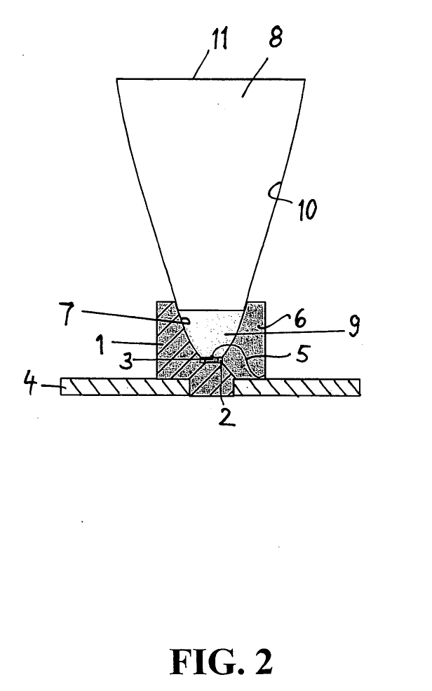

A first embodiment of the invention is in principle shown by FIG. 2. The drawing shows a micro-structured sub-mount 1, which has a flat blind hole 2 for exactly fitting in an LED chip 3. In the drawing a gap can be seen right and left of the chip 3, since the blind hole 2 adjusts the chip 3 over its corners. The sub-mount 1 is set onto a carrier substrate 4, such as printed circuit board, lead frame, TO housing or the like. The LED chip 3 is electrically connected by means of at least one bond wire 5 extending from the chip surface to the carrier substrate 4. In order to be able to guide the bond wire 5 to the carrier substrate 4, a slot 6 is formed in the micro-structured sub-mount 1, through which slot the bond wire 5 extends. Depending on the LED type the second contact is either realized by a second bond wire (isolated LED substrates such as sapphire) or the chip is connected on its rear contact via the electrically conductive carrier substrate 4 and the electrically conductive sub-mount 1.

Furthermore, a paraboloidal reflector 7 is formed in the sub-mount, which is designed such that the focal point of the paraboloid is located exactly in the center of the surface of the LED chip 3. The sub-mount 1 with its reflector 7 must therefore be adapted to the geometric shape of the LED chip 3. Thus, the technical possibility exists to start with the beam formation in the direct proximity of the chip 3 whereby finally the dimensional size and dimensional height can be optimized.

In this respect, the structure corresponds to the prior art according to the cited WO 02/054129 A1.

In order to extend the reflector, according to the invention a reflector body 8 consisting of transparent plastics (e.g. PMMA or PC) or clear glass is inserted into the reflector opening of the sub-mount 1, said reflector body when being inserted aligning precisely (i.e. by precise within some μm) in the axial direction of the reflector 7 within the sub-mount 1. A transparent liquid plastic material 9 is filled between the LED chip 3 and the reflector body 8, said plastic material filling the entire free space of the sub-mount 1 in a bubble-free manner. Light from the LED chip 3 which is incident onto the paraboloidal surface 10 of the reflector body 8 not in the sub-mount reflector 7 but in the reflector body 8 has an angle to the surface of incidence that is so small that it is totally reflected. Even without a metallization of the reflector body 8 does a 100% light reflection take place.

The arrangement according to the invention now has the further advantage that the light loss caused by the required slot 6 extending through the reflector surface 7 of the sub-mount can at least partially be compensated by reflection at the reflector body 8. In practice it is advantageous if the reflector body 8 projects into the sub-mount 1 as far as possible except for a minimum distance to the bond wire 5 of the LED chip 3. The light loss caused by the slot 6 is thereby minimized.

The reflector body 8 is preferably an injection molded plastic part whose length and diameter at its light-emitting outer opening 11 being flexibly adaptable to the respective demands of the object. Glass, particularly quartz glass can, however, also be used as a material of the reflector body. A modification of the sub-mount 1 that is laborious to manufacture is not required. If e.g. the radiation angle shall be minimized, only a different reflector body 8 must be set onto the sub-mount 1.

The peripheral wall of the reflector body 8 that forms the reflector surface 10 extending between the irradiation surface and the radiation surface is preferably high gloss finished.

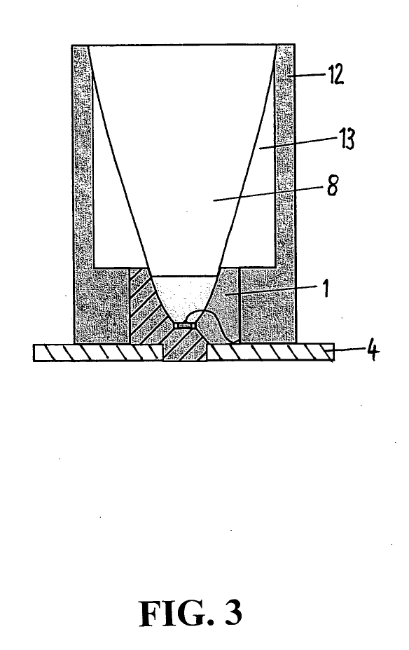

The arrangement is preferably mechanically secured in the outer portion by a housing 12. This housing should preferably also center itself at the sub-mount 1 so that the entire component leads to an arrangement as in FIG. 3. A housing 12 can be recognized in FIG. 3, which contacts the reflector body 8 as little as possible so that light does not emerge from the reflector body 8 at the contact portion. A mechanical fixing must, of course, be given. Material 13 of low refractive index shall be located between the reflector body 8 and the housing 12, so that the reflector body 8 totally reflects the beams incident also at greater incident angles. The precise geometry and selection of the material depend on the concrete design. Air (n=1) but also silicon (n≈1.4) may be used as filling material of the gap.

The reflector body 8 may be extended upwards over the sub-mount 1. It advantageously consists e.g. of a piece of optical waveguide whose end portion has the desired paraboloidal cross section. In order to connect an optical waveguide to this optical fiber a ferrule construction may be used (not shown) which centers a ferrule on the sub-mount 1, said ferrule have a bore that receives the free end portion of the reflector body 8 projecting from the sub-mount 1 and having such a length that may also precisely accommodate in an accurately matched manner the end portion of the optical waveguide. The opposing end faces of the reflector body 8 and of the optical waveguide are preferably ground and polished perpendicular to their axes and directly abut one another. A transparent adhesive film may possibly also be provided between said end faces.

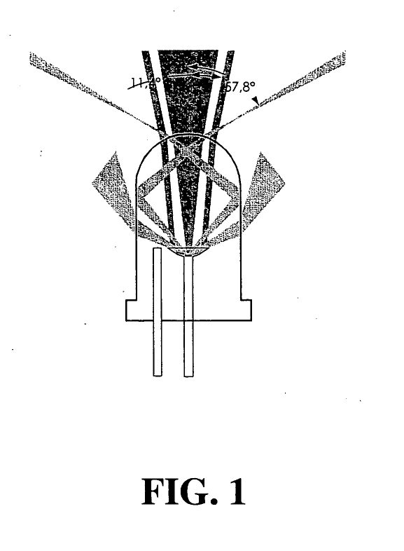

The advantage of the two arrangements according to FIGS. 2 and 3 compared to the prior art is that in these arrangements the beam formation starts in the direct surroundings of the LED chip 3. With an overall size of a diameter of e.g. 3 mm and a height of 5 mm the light of a conventional LED chip may be coupled into an angular portion of ±20° in a loss-free manner. This overall size is needed by a conventional LED according to FIG. 1 only for the plastic housing without having made a significant beam formation.

If very narrow radiation angles are to be realized, overall sizes of e.g. a length of 10 mm and an opening diameter of 5 mm and a maximum radiation angle of ±14° result from the structure of the invention. The above-mentioned reflector attachment of the company Osram achieves a maximum radiation angle of ±31° only, with a length of 10 mm and an opening diameter of 12 mm.

By the structure according to the invention, the radiation angle can be reduced by a factor larger than 2 while at the same time the overall height is maintained. At the same time a significant reduction of the reflector diameter is achieved.

The reflector body may also be designed with a geometry acting as a beam former only in a single space direction in that it is linearly extended while maintaining a paraboloidal cross section in a direction orthogonal to the cross section so that a respectively profiled disk or rail is provided, or by closing same into the shape of a torus forming a disc provided with a central opening.

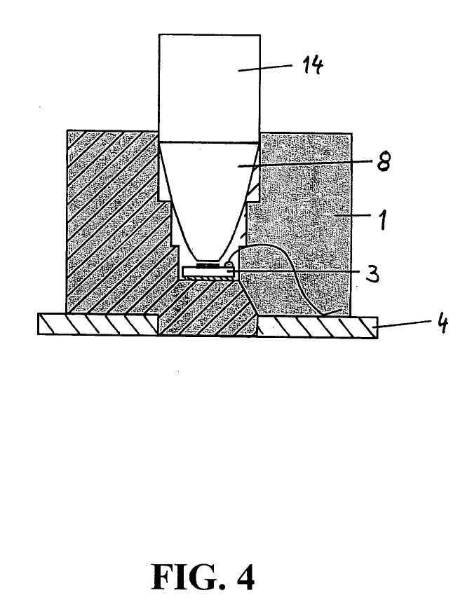

FIG. 4 shows a reflector geometry that consists of a flat disc 8a, with FIG. 4a showing a cross section and FIG. 4b showing a top view. It can be recognized that at the edge where the two surfaces 15 that are paraboloidally bulged in cross section approach one another, several LEDs are arranged adjacently through their sub-mounts 1 so that they may together radiate into the reflector body 8a: The radiating end face 11a opposing said edge then appears as a light band. It is self-evident that in this case the openings of the sub-mounts 1 are not formed rotationally-symmetrical but comprise two reflection surfaces opposing one another, which together with an imaginative section place extending perpendicular thereto form paraboloidal lines of intersection.

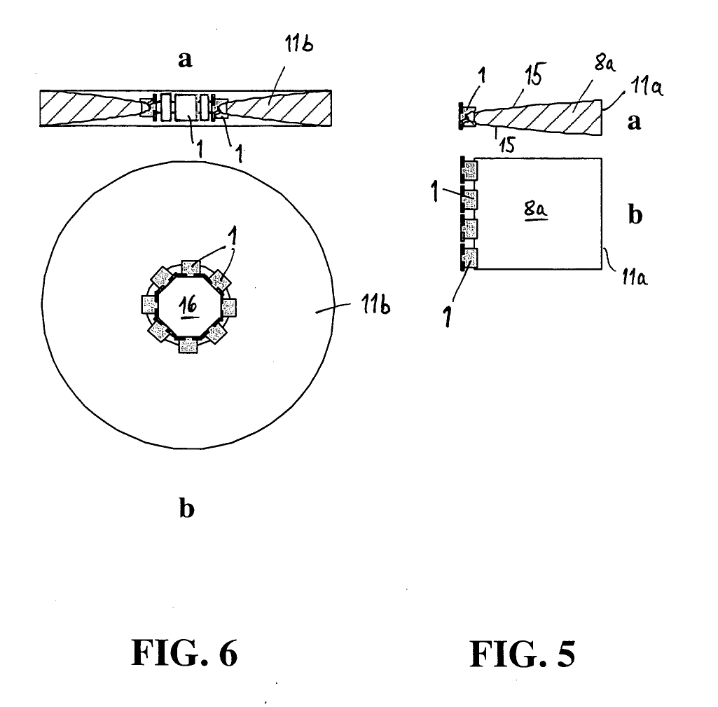

The embodiment according to FIGS. 5a and 5b can e.g. be used as an all-around beacon for maritime applications or for the illumination of only one room plane in living rooms or office rooms. In this embodiment, according to FIG. 5b the reflector body 8b is a disc having an opening 16 in its interior, which is delimited by a cylindrical light entrance surface. The upper and lower lateral surfaces of the reflector body 8b in the drawing have, according to FIG. 5a, such a curvature that together with an axial intersecting plane they form mirror-inverted, paraboloidal lines of intersection that approach one another in the direction towards the edge of the opening 16. At this edge a plurality of LED chips are arranged through their sub-mounts in juxtaposition in a star-shaped alignment, comparable to the embodiment of FIG. 4b, and therefore they radiate radially outwardly into the reflector body 11b. LEDs of different colors may be combined to form white light or any other color, or light of different colors may be radiated from the cylindrical outer peripheral surface 11b of the reflector body, as is required in many practical applications, without color filters having to be used that attenuate the light intensity of the beacons operated with light bulbs. It is self-evident that in this embodiment the sub-mounts 1 do not have any rotational-symmetrical recesses but are designed in a manner as explained above with reference to the embodiment of FIGS. 4a and 4b.

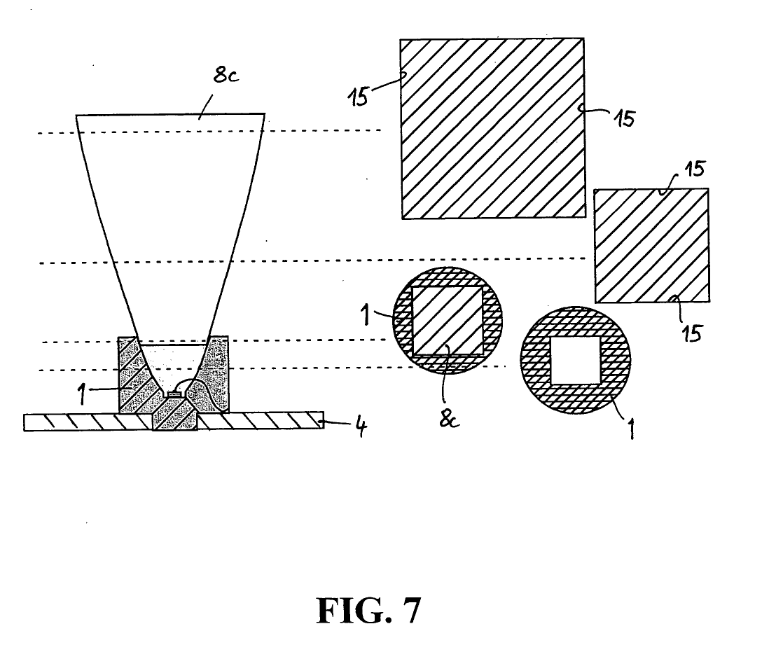

For reasons of product design or because of specially predetermined installation conditions it might be required to form the rotational-symmetric reflector bodies and sub-mounts according to FIGS. 2 and 3 by reflector bodies with square cross sections perpendicular to the reflector axis. The rotational paraboloid then becomes a reflector body 8c, whose four lateral surfaces 15 are curved parabolically in one plane. FIG. 6 shows this structure with different cross sectional surfaces in different heights of the reflector body 8c. Since the manufacture of tools having surfaces that do not have rotational-symmetric surfaces is significantly more complex, this design will only be used under specially predetermined ancillary conditions.

1. A light diode arrangement with a reflector, comprising a sub-mount on which a light-emitting diode chip is mounted, and a reflector aligned at the sub-mount, said sub-mount comprising a reflector surface located in a beam path of the light-emitting diode chip, wherein the sub-mount comprises a blind hole into which the light-emitting diode chip is inserted and which comprises a paraboloidal reflector surface disposed above the blind hole, said reflector surface having one of a focal point and focal line a center of a surface of the light-emitting diode chip is located, the reflector is formed by a solid body formed of a transparent material and comprising a small irradiation surface opposing the light-emitting diode chip and a large radiation surface opposing same at a distance, between which a lateral surface forming the reflector surface extends, and the sub-mount comprises an opening above the blind hole into which the reflector body is inserted with the irradiation surface first so that its reflector surface forms a continuation of the reflector surface of the sub-mount.

2. A light-emitting diode arrangement as claimed in claim 1, wherein the reflector body is a rotational-symmetric body having an axis in which the LED chip is arranged.

3. A light-emitting diode arrangement as claimed in claim 2, wherein the reflector surfaces of the sub-mount and of the reflector body are each formed paraboloidal.

4. A light-emitting diode arrangement as claimed in claim 1 or 2, wherein the reflector body is held by a ferrule centered on the sub-mount.

5. A light-emitting diode arrangement as claimed in claim 1, wherein the reflector surface of the reflector body is formed by four lateral surfaces adjoining one another, of which at least two opposing lateral surfaces generate a paraboloidal intersecting line on a plane vertically intersecting the lateral surfaces and the LED chip, wherein the four lateral surfaces and planes vertically intersecting said plane form lines of intersection which perpendicularly intersect one another.

6. A light-emitting diode arrangement as claimed in claim 5, wherein said two paraboloidally formed lateral surfaces of the reflector body have an extension transversely to a paraboloidal extension that is much larger than respective dimensions of the other lateral surfaces of the reflector body and that the irradiation surface of the reflector body is opposed by a plurality of adjoining LED chips that are held on the reflector body by means of their sub-mounts.

7. A light-emitting diode arrangement as claimed in claim 4, wherein the reflector body is one of a circular disc and a sector of a disc that has a circular opening in a center, said opening being delimited by an irradiation surface, and the disc and the disc sector, respectively, has an outer periphery that is delimited by a radiation surface, wherein the irradiation surface and the radiation surface each have cylinder surfaces being axially parallel, and lateral surfaces connecting same form paraboloidal lines of intersection with an axial intersecting plane, that approach one another in a direction towards the center of the disc or disc sector, and that the irradiation surface is opposed by a plurality of adjoining, star-like aligned LED chips that are held on the reflector body by means of their sub-mounts.

8. A light-emitting diode arrangement as claimed in one of claims 1 and 2, wherein the reflector surfaces of the reflector body are polished.

9. A light-emitting diode arrangement as claimed in claim 1 or 2, wherein the space between the LED chip and the irradiation surface of the reflector body is filled with a transparent, cured liquid plastic.
